(19) United States
(12) Patent Application Publication
(10) Pub. No.: US 2011/0188195 A1
(43) Pub. Date: Aug. 4, 2011

(54) CUSTOMER REPLACEABLE UNIT DRIVE ISOLATOR

(76) Inventors: Tanja Scherf-Smith, St. Petersberg, FL (US); Ethan Weber, Goodard, KS (US)

(21) Appl. No.: 12/600,877

(22) PCT Filed: Sep. 2, 2008
(86) PCT No.: PCT/US08/75045

§ 371 Date: Nov. 19, 2009

(51) Int. Cl. G06F 1/16; H05K 7/00; B29C 45/14

(52) U.S. Cl. 361/679.37; 264/279

(57) ABSTRACT

Disclosed is a customer replaceable unit that uses an overmolded plastic to isolate the disk drive from the customer replaceable unit frame. By isolating the disk drive from the customer replaceable unit frame, input/output operations are not disrupted as a result of vibration and shocks from the chassis in which the customer replaceable unit is inserted.

### CROSS-REFERENCE TO RELATED APPLICATION

### Background of the Invention

Customer replaceable units have provided a convenient and simple of way of replacing appliances such as disk drives in servers, RAID devices, etc. Drives, such as hot spares, mirror drives in a RAID unit, or any type of replacement drive can be easily removed or replaced using customer replaceable unit devices. Disk drives can be plugged and unplugged from the chassis of RAID units, servers, computers, etc. with cables having connectors that connect to the back of the unit. Hence, the customer replaceable unit devices have been found to be a practical and convenient way to replace appliances, such as disk drives, that are utilized in the computer and electronics industry.

### SUMMARY OF THE INVENTION

An embodiment of the present invention may therefore comprise a method of isolating a disk drive from a customer replaceable unit to improve input and output operations of the disk drive comprising: providing a customer replaceable unit frame having at least two support arms; forming openings in the at least two support arms to support the disk drive on the at least two support arms with connectors that pass through the openings and connect to the disk drive; overmolding an elastomeric material, that is capable of absorbing vibrations, on the at least two support arms in locations between the disk drive and the at least two support arms, and around surfaces of the at least two support arms surrounding the openings, and portions of the at least two support arms that are in contact with the connectors when the connectors are placed in the openings and are connected to the disk drive, so as to isolate the disk drive from the customer replaceable unit frame with the elastomeric material.

An embodiment of the present invention may further comprise a customer replaceable unit that increases the occurrence of successful input/output operations of a disk drive mounted in the customer replaceable unit comprising: a customer replaceable unit frame having at least two support arms, the support arms having a plurality of support arm openings formed therein, the support arm openings aligned with a plurality of disk drive support openings on the disk drive; a plurality of connectors inserted through the support arm openings and the disk drive support openings to support the disk drive in the customer replaceable unit frame; an elastomeric material that is overmolded on the at least two support arms in locations between the disk drive and the at least two support arms, around surfaces of the at least two support arms surrounding the support arm openings, and portions of the at least two support arms that are in contact with the plurality of connectors that are inserted through the support arm openings, so that the disk drive is substantially isolated from the customer replaceable unit frame by the elastomeric material.

### BRIEF DESCRIPTION OF THE DRAWINGS

FIG. 1 is schematic perspective view of an embodiment of a customer replaceable unit.

FIG. 2 is a schematic perspective view of a customer unit frame of the embodiment of FIG. 1.

FIG. 3 is a schematic side view of a portion of the customer replaceable unit of FIG. 1.

FIG. 4 is a schematic perspective view of a portion of the frame that is illustrated in FIG. 2.

FIG. 5 is a schematic perspective view of the portion of the frame illustrated in FIG. 2 with overmolding.

FIG. 6 is a schematic perspective view of an opening in the frame showing overmolding around the opening.

### DETAILED DESCRIPTION OF THE EMBODIMENTS

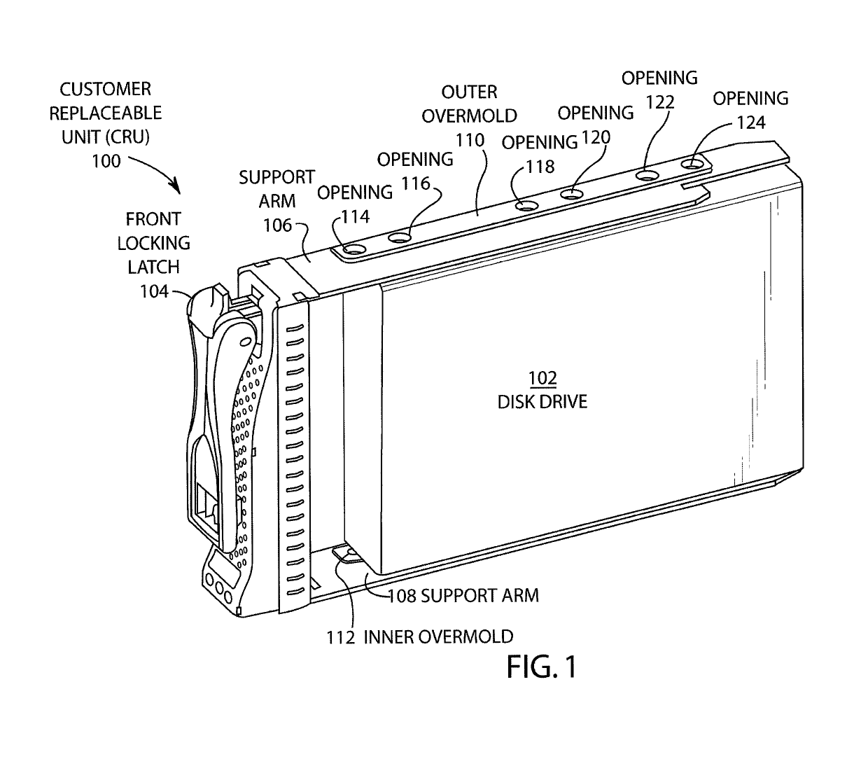

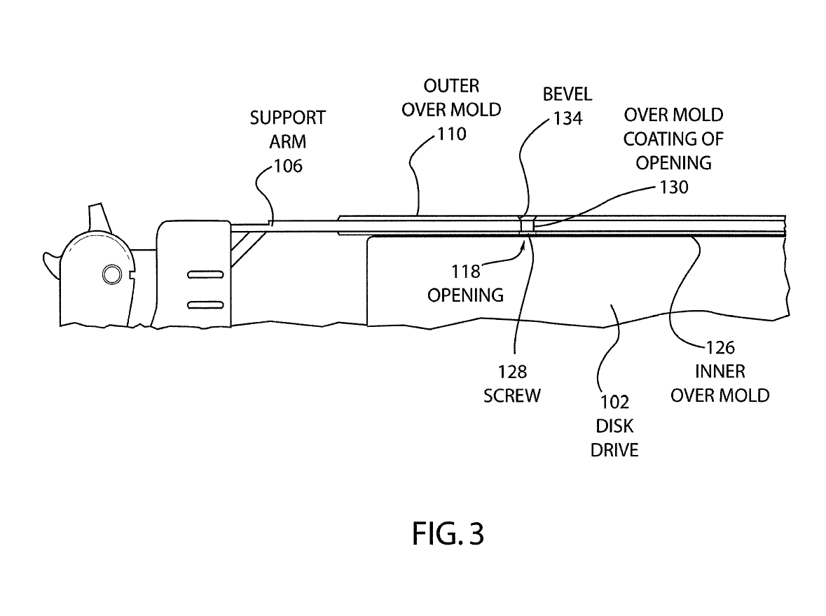

FIG. 1 is a schematic perspective view of one embodiment of a customer replaceable unit (CRU) 100. The embodiment of the CRU 100 includes a disk drive 102, a front locking latch 104, a support arm 106 and a support arm 108. Support arm 106 includes an outer overmold 110 and an inner overmold 126 (FIG. 3). Support arm 108 includes an inner overmold 112 and an outer overmold (not shown) that is similar to outer overmold 110. The outer overmold 110 and the support arm 106 have a series of openings 114, 116, 118, 120, 122 and 124 that are adapted to receive connectors, such as screws, that attach to the disk drive 102 to hold the disk drive 102 to the support arm 106. Similar openings are formed in the support arm 108, the inner overmold 112 and the outer overmold (not shown) on the outer portion of support arm 108, to hold the disk drive 102 to the support arm 108. The support arms 106, 108 fit within a chassis of a device, such as a server or RAID storage device, to allow replacement of the disk drive 102. The CRU 100 can be easily inserted in and removed from the chassis using the front locking latch 104. The front locking latch 104 securely holds the CRU 100 in place in the chassis.

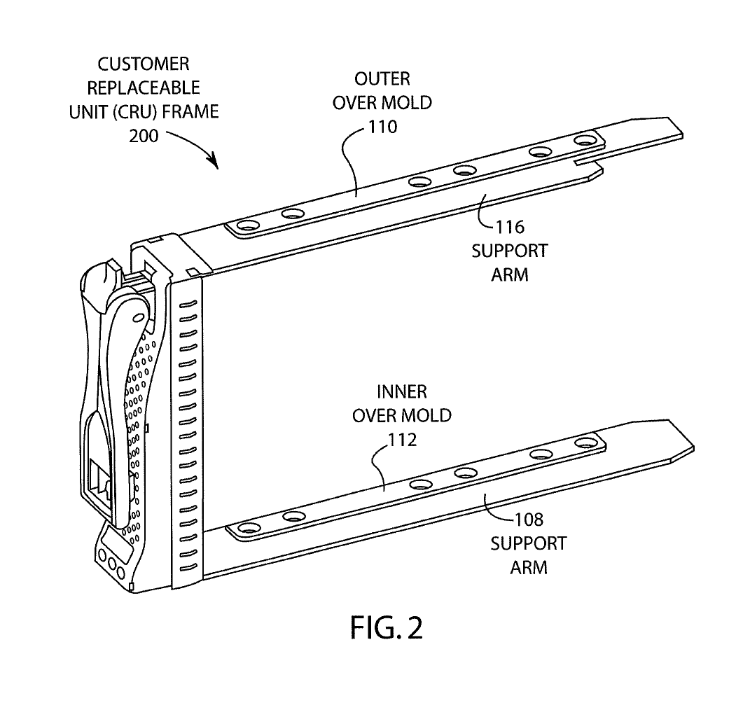

The embodiment of the CRU 100 illustrated in FIG. 2 provides isolation between the customer replaceable unit frame 200 (FIG. 2) and the disk drive 102. This isolation is provided by the overmolding shown in the figures. The overmolding such as inner overmold 112 and inner overmold 126 (FIG. 3), is positioned between the disk drive 102 and the support arm 108 and the support arm 106, respectively. The overmolding material can be any type of plastic or elastomer that is sufficiently soft to substantially reduce the transmission of vibrations and shocks from the customer replaceable unit frame 200 to the disk drive. For example, the overmolding may comprise any desired type of rubber material or synthetic rubber material, such as urethane rubber. In one embodiment, urethane 50 A dur textured rubber is used. For purposes of this specification, the term plastic and plastic material is used to describe any of the desired soft plastics, urethanes, both natural and synthetic rubbers and other materials that can be molded onto the customer replaceable unit frame 200 to isolate the disk drive 102 from the customer replaceable unit frame 200.

Referring again to FIG. 2, the outer overmold 110 and inner overmold 112, as well as the inner overmold 126 and the outer overmold on support arm 108 (not shown), are molded to the support arms 106, 108 using standard overmolding techniques. The overmolded layers of plastic are sufficiently thin to not interfere with the operation of the customer replaceable unit 100 during insertion in and removable from the chassis. The molding process secures the elastomeric material to the support arms 106, 108 which can be made of various materials including metal, ABS or other plastic materials. The outer overmold 110 and the inner overmold 126 (FIG. 3) are on both sides of the support arm 106. The overmolded plastic material covers all of the surfaces of the openings 114-124 including the beveled surfaces and cylindrical surfaces illustrated in FIGS. 1 and 2. In this manner, connectors that pass through the openings 114-124, and similar openings on support arm 108, and connect to the disk drive 102 to hold the disk drive 102 to the support arms 106, 108, so that the disk drive 102 is isolated by the plastic overmolded material. In other words, the plastic overmolded material that is placed on support arms 106, 108 is placed between the support arms 106, 108 and the disk drive 102, around the inside surfaces of the holes in the support arms 106, 108 and on the outer surfaces of the support arms 106, 108, including bevels, so that connectors, such as screws that are inserted through the openings in the support arms 106, 108, only contact the plastic overmolded material. Further, the sides of the disk drive only contact the plastic overmolded material to provide further isolation. Since the plastic overmolded material is softer than the material of support arms 106, 108 the plastic overmolded material absorbs shocks and vibrations and functions to isolate the disk drive 102 from shocks and vibrations transmitted to the customer replaceable unit frame 200 from the chassis of the RAID device, server, etc.

FIG. 3 is a schematic side view of a portion of the customer replaceable unit frame 200. As shown in FIG. 3, support arm 106 is covered with an outer plastic overmold 110 on the outer surface of the support arm 106 and an inner plastic overmold 126 on the inner surface of the support arm 106. The inner overmold 126 is disposed between the disk drive 102 and the support arm 106 so that the disk drive 102 is isolated from the support arm 106. As also shown in FIG. 3, a screw 128 is inserted through opening 118 in the support arm 106 and is connected to the disk drive 102 to support the disk drive to the support arm 106. Of course, other screws are mounted through other holes in the support arm 106 that are not shown in FIG. 3. As can be seen in FIG. 3, there is an overmold coating 130 in the opening 118 that isolates the screw 128 from the structure of the support arm 106. Further, the screw 128 is in contact with the outer overmold 110 in the bevel 134 of the opening 118.

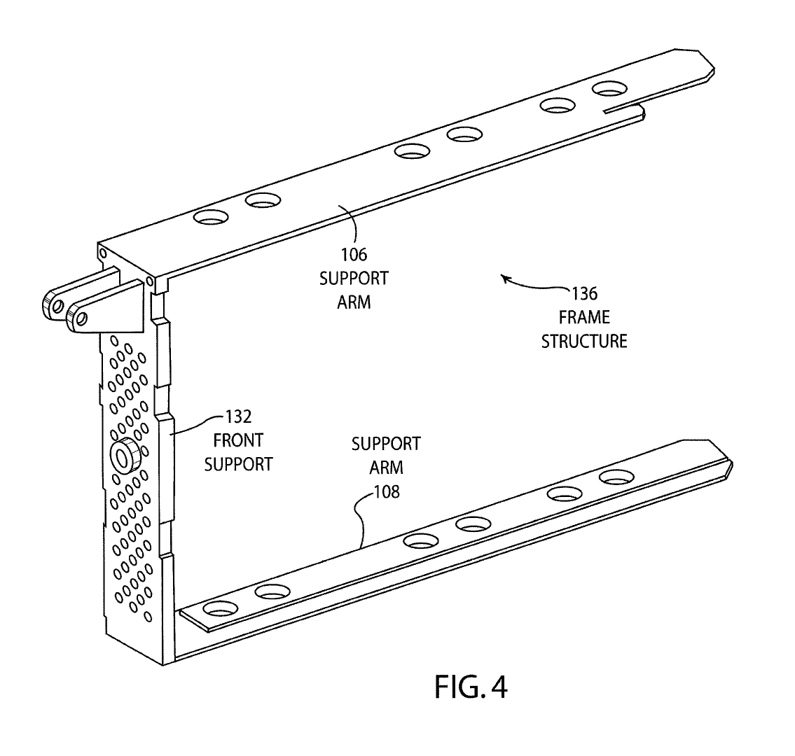

FIG. 4 is a schematic perspective view of the customer replaceable unit frame structure 136. As shown in FIG. 4, front support 132 is connected to support arm 106 and support arm 108. Front support 132, support arm 106 and support arm 108 can be molded as a unitary structure from ABS plastic or other plastic materials. Alternately, the frame structure 136 illustrated in FIG. 4 can be fabricated from metal. Both the plastic and metal frame structure 136 can be overmolded with the plastic overmolding to provide isolation between the disk drive 102 and the frame structure 136 that is illustrated in FIG. 4. Again, various types of hard and durable plastics and composite materials can be used for the frame structure 136 that is illustrated in FIG. 4.

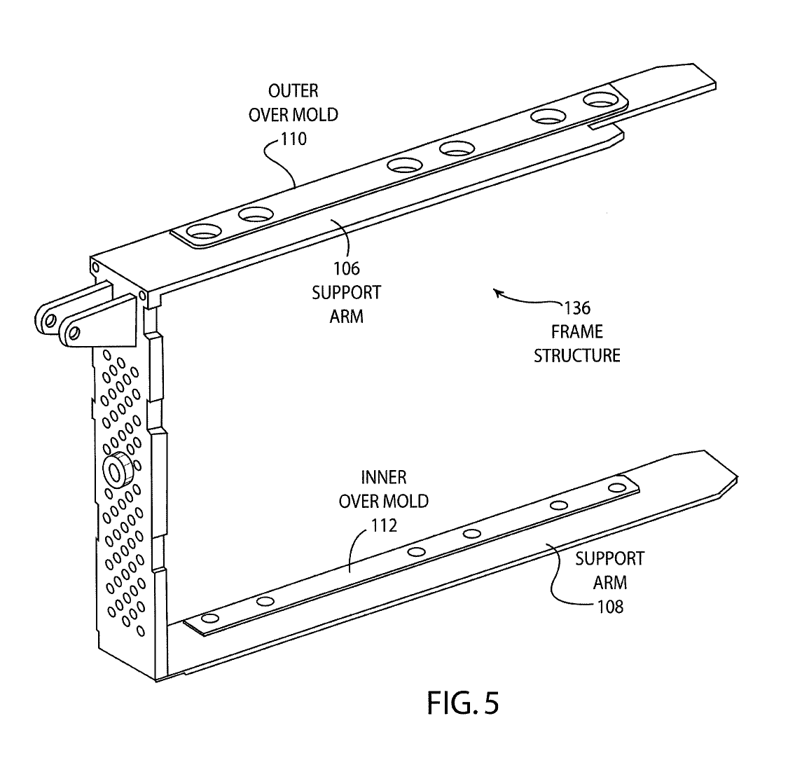

FIG. 5 is a schematic perspective view of the frame structure 136, that is illustrated in FIG. 4, illustrating the plastic material overmolded on the frame structure 136. As shown in FIG. 5, the outer overmold 110 and the inner overmold 112 are molded onto the frame structure 136 in the manner described above. In addition, an inner overmold 126 (FIG. 3) and an outer overmold (not shown) on support arm 108 are also molded onto the opposite sides of the support arms 106, 108. The overmolding process is performed so that the bevel structures of the openings are maintained and the overmold material passes through the openings in the support arms 106, 108, to the other side of the support arms 106, 108, to form a unitary overmold structure. This single unitary structure of the overmolded plastic helps to secure the plastic material to the support arms 106, 108.

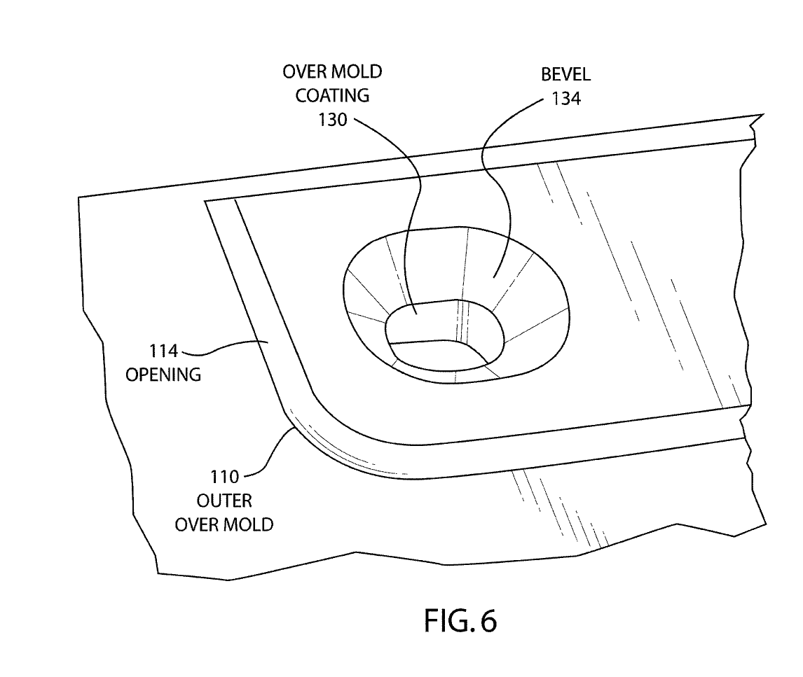

FIG. 6 is a schematic perspective view of a portion of the support arm 106 showing opening 114. As shown in FIG. 6, the outer overmold 110 covers the bevel 134 and the opening 114. An overmold coating 130 covers all of the surfaces of the opening 114 so that the opening 114 is completely surrounded by an overmolded plastic. In this fashion, the connector, such as a screw that is inserted through the opening 114, contacts the overmold coating 130 on the interior portion of the opening 114 and the bevel 134, and does not contact the support arm 106 at any location.

Hence, the overmolded plastic that is placed upon the support arms 106, 108 isolates the disk drive 102 from shocks and vibrations transmitted by the support arms 106, 108 from the chassis in which a customer replaceable unit is used. By isolating the disk drive 102, fewer input/output operations fail, and the disk drive operates in a more effective manner. Further, rotational vibration springs that are normally added to the customer replaceable unit can be eliminated, and the input/output functions of the drive are increased. Not only are the input/ouput operations increased, the variance in the number of successful operations is very low. All of these advantages lead to a more stable customer replaceable unit.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A method of isolating a disk drive from a customer replaceable unit to improve input and output operations of said disk drive comprising:
providing a customer replaceable unit frame having at least two support arms;
forming openings in said at least two support arms to support said disk drive on said at least two support arms with connectors that pass through said openings and connect to said disk drive;
overmolding an elastomeric material, that is capable of absorbing vibrations, on said at least two support arms in locations between said disk drive and said at least two support arms, and around surfaces of said at least two support arms surrounding said openings, and portions of said at least two support arms that are in contact with said connectors when said connectors are placed in said openings and are connected to said disk drive, so as to isolate said disk drive from said customer replaceable unit frame with said elastomeric material.

2. The method of claim 2 wherein said process of overmolding an elastomeric material further comprises:
overmolding urethane 50 A rubber on said at least two support arms.

3. The method of claim 2 wherein said process of providing a customer replaceable unit frame comprises:
providing a customer replaceable unit made from ABS.

4. The method of claim 2 wherein said process of providing a customer replaceable unit frame comprises:
providing a customer replaceable unit made from metal.

5. A customer replaceable unit that increases the occurrence of successful input/output operations of a disk drive mounted in said customer replaceable unit comprising:
a customer replaceable unit frame having at least two support arms, said support arms having a plurality of support arm openings formed therein, said support arm openings aligned with a plurality of disk drive support openings on said disk drive;
a plurality of connectors inserted through said support arm openings and said disk drive support openings to support said disk drive in said customer replaceable unit frame;
an elastomeric material that is overmolded on said at least two support arms in locations between said disk drive and said at least two support arms, around surfaces of said at least two support arms surrounding said support arm openings, and portions of said at least two support arms that are in contact with said plurality of connectors that are inserted through said support arm openings, so that said disk drive is substantially isolated from said customer replaceable unit frame by said elastomeric material.

6. The customer replaceable unit of claim 5 wherein said elastomeric material comprises a urethane 50 A rubber.

7. The customer replaceable unit of claim 6 wherein said customer replaceable unit frame is made from ABS.

8. The customer replaceable unit of claim 6 wherein said customer replaceable unit frame is made from metal.
